(19) United States
(12) Patent Application Publication
(10) Pub. No.: US 2025/0154643 A1
(43) Pub. Date: May 15, 2025

(54) AREA SELECTIVE DEPOSITION OF METALS FOR ELECTRONIC DEVICES

(71) Applicant: Tokyo Electron Limited, Tokyo (JP)

(72) Inventors: Kai-Hung Yu, Albany, NY (US); Ryota Yonezawa, Albany, NY (US); Yuji Otsuki, Nirasaki City (JP); Hidenao Suzuki, Albany, NY (US); Robert D. Clark, Leuven (BE); Gyanaranjan Pattanaik, Albany, NY (US)

(21) Appl. No.: 18/937,950

(22) Filed: Nov. 5, 2024

Related U.S. Application Data
(60) Provisional application No. 63/548,527, filed on Nov. 14, 2023.

(51) Int. Cl. C23C 16/04; C23C 16/16; C23C 16/455; H01L 21/768

(52) U.S. Cl. CPC C23C 16/04; C23C 16/16; C23C 16/45534; H01L 21/76876

(57) ABSTRACT

Method for area selective deposition (ASD) on a substrate containing a growth surface that is exposed and a non-growth surface that is exposed. The method includes cyclical exposures of a deposition gas containing a metal carbonyl precursor, the metal carbonyl precursor decomposing on the growth surface such that a metal film is deposited on the growth surface and carbon monoxide (CO) gas is released, and an inhibitor gas after stopping the flow of the deposition gas to the substrate. The cycling between flowing the deposition gas to the substrate and flowing the inhibitor gas to the substrate is repeated to selectively form the metal film on the growth surface relative to the non-growth surface, where the inhibitor gas increases the selectivity of the metal film formed on the growth surface when compared to the selectivity of the metal film formed on the growth surface without the inhibitor gas.

### CROSS REFERENCE TO RELATED PATENTS AND APPLICATIONS

This application claims priority to and the benefit of the filing date of U.S. Non-Provisional Patent Application No. 63/548,527, filed Nov. 14, 2023, which application is incorporated herein by reference in its entirety.

### FIELD OF THE INVENTION

This disclosure relates to metal deposition techniques including techniques for area selective deposition of metals for microelectronic devices.

### BACKGROUND OF THE INVENTION

Area selective deposition (ASD) is an advanced self-aligned patterning technique that may be used in manufacturing microelectronic devices. ASD is a process that can be used to deposit materials in exact areas on different exposed layers on a substrate and thereby reduce the number of lithography and etch steps in a manufacturing flow. During ASD, deposition selectivity between the different exposed layers is often lost or reduced, and material starts to deposit on areas not targeted for deposition in addition to the targeted deposition areas. New ASD methods that improve deposition selectivity are therefore needed.

### SUMMARY OF THE INVENTION

Methods are provided for area selective deposition (ASD) on a substrate, including selective metal deposition on growth surfaces relative to non-growth surfaces. The growth surfaces can include metal surfaces that are exposed and the non-growth surfaces can include dielectric surfaces that are exposed, for example.

In one embodiment, the method includes providing a substrate containing a growth surface that is exposed and an non-growth surface that is exposed, flowing a deposition gas containing a metal carbonyl precursor to the substrate, the metal carbonyl precursor decomposing on the growth surface such that a metal film is deposited on the growth surface and carbon monoxide (CO) gas is released, stopping the flow of the deposition gas to the substrate, and flowing an inhibitor gas to the substrate after stopping the flow of the deposition gas to the substrate. The method further includes repeatedly cycling between flowing the deposition gas to the substrate and flowing the inhibitor gas to the substrate, where the cycling selectively forms the metal film on the growth surface relative to the non-growth surface, and where the flowing the inhibitor gas increases the selectivity of the metal film formed on the growth surface when compared to the selectivity of the metal film formed on the growth surface without flowing the inhibitor gas.

In another embodiment, the method includes providing a substrate containing a metal surface that is exposed and a non-metal surface that is exposed, flowing a deposition gas containing a ruthenium (Ru) carbonyl precursor to the substrate, the ruthenium carbonyl precursor decomposing on the metal surface such that a Ru metal film is deposited on the metal surface and carbon monoxide (CO) gas is released, stopping the flow of the deposition gas to the substrate, and flowing an inhibitor gas to the substrate after stopping the flow of the deposition gas to the substrate. The method further includes repeatedly cycling between flowing the deposition gas to the substrate and flowing the inhibitor gas to the substrate, where the cycling selectively forms the Ru metal film on the metal surface relative to the dielectric surface, and where the flowing the inhibitor gas increases the selectivity of the Ru metal film formed on the metal surface when compared to the selectivity of the Ru metal film formed on the metal surface without flowing the inhibitor gas.

In yet another embodiment, the method includes providing a substrate containing an metal surface that is exposed and a non-metal surface that is exposed, where the metal surface has a plurality of different grain orientations, flowing a deposition gas containing a metal carbonyl precursor to the substrate, the metal carbonyl precursor decomposing on the metal surface such that a metal film is deposited on the metal surface and carbon monoxide (CO) gas is released, stopping the flow of the deposition gas to the substrate, and flowing an inhibitor gas to the substrate after stopping the flow of the deposition gas to the substrate. The method further includes repeatedly cycling between flowing the deposition gas to the substrate and flowing the inhibitor gas to the substrate, where the cycling selectively forms the metal film on the metal surface relative to the dielectric surface, and where the flowing the inhibitor gas increases the thickness uniformity of the metal film formed on the plurality of different grain orientations when compared to the selectivity of the metal film formed on the plurality of different orientations without flowing the inhibitor gas.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 depicts a schematic view of a deposition system for metal deposition according to an embodiment of the invention;

FIG. 2 schematically shows gas flows during cyclical Ru metal deposition according to an embodiment;

FIGS. 3A and 3B schematically shows selective metal deposition on a growth surface relative to a non-growth surface according to an embodiment;

FIG. 3C schematically shows non-selective metal deposition on a growth surface relative to a non-growth surface;

FIGS. 4A-4C schematically show through cross-sectional views non-cyclical deposition where metal is deposited on a growth surface;

FIGS. 5A-5C schematically show through cross-sectional views cyclical deposition where metal is deposited on a growth surface according to an embodiment;

FIGS. 6A and 6B schematically show selective metal deposition on a growth surface relative to a non-growth surface in a recessed feature according to an embodiment;

FIG. 7 shows a cross-sectional micrograph image of Ru metal deposition on Cu metal grains with different grain orientations; and

FIGS. 8A and 8B show top view scanning electron micrographs (SEM) of Ru metal films deposited on Cu metal films.

### DETAILED DESCRIPTION OF SEVERAL EMBODIMENTS

Methods for improving deposition selectivity during area selective deposition (ASD) are described in several embodiments. Some embodiments describe methods for improving deposition selectivity during ASD of metal films on growth surfaces relative to non-growth surfaces. The growth surfaces can include metal surfaces that are exposed and the non-growth surfaces can include dielectric surfaces that are exposed, for example.

Metal on metal area selective deposition (ASD) has several utilities in semiconductor manufacturing, including interconnect fabrication, seed layer deposition, contact formation, fabrication of metal gates, and metallization patterning, for example.

In semiconductor devices, interconnects play a crucial role in connecting various components and transferring electrical signals. Metal on metal ASD can be used to selectively deposit metal films onto pre-defined metal interconnects, enabling precise control over the interconnect geometry and electrical properties. This allows for improved device performance, reduced resistance, and enhanced reliability.

Metal on metal ASD can be employed to selectively deposit seed layers on specific areas of a substrate. Seed layers are thin metal films that serve as nucleation sites for subsequent metal deposition. By selectively depositing seed layers, ASD facilitates controlled metal growth, especially in complex device structures requiring distinct metallization patterns.

Metal contacts are used to establish electrical connections between different layers or components. Metal on metal ASD can be utilized to selectively deposit metal contacts onto specific regions, ensuring precise contact placement and minimizing the risk of short circuits or unwanted electrical connections.

Metal gates are critical components in semiconductor transistors, controlling the flow of current. Metal on metal ASD enables the selective deposition of metal gates onto specific areas of the transistor structure, ensuring precise gate placement and optimizing transistor performance.

Metal on metal ASD can be employed as a maskless patterning technique, allowing for the direct deposition of metal films in desired areas. This eliminates the need for lithographic masks, simplifying the manufacturing process and reducing production costs.

Chemical vapor deposition (CVD) and atomic layer deposition (ALD) are techniques used to deposit thin films of materials by chemical reaction of precursor gases on exposed surfaces. Metal carbonyls are commonly used in CVD and ALD to deposit metal and metal-containing films onto a substrate. Metal carbonyls serve as the precursor gases that provide the metal atoms required for film deposition. As the metal carbonyl gas flows over the substrate, a portion of the metal carbonyl molecules will be adsorbed on the substrate surface, a portion of the adsorbed metal carbonyl molecules will decompose due to the high temperature of the substrate surface, and releasing metal atoms and carbon monoxide gas. The metal atoms typically react with the surface of the substrate at favorable nucleation sites where the resulting metal atoms can bond to the substrate surface. These bonded metal atoms act as nucleation sites themselves forming metal nuclei which expand as more metal atoms deposit and eventually coalesce into a thin layer of metal film.

The key for area selective deposition (ASD) is to reduce the growth rate on the non-growth surface by passivating nucleation sites and selecting process conditions that do not create new nucleation sites on the non-growth surface. Embodiments of the invention achieve this using alternating cycling exposures of a deposition gas containing a metal carbonyl and an inhibitor gas, where the inhibitor gas likely passivates nucleation sites on the non-growth surface. This results in greatly reduced metal deposition rate on the non-growth surface but the metal deposition rate on the growth surface is only slightly reduced as the growth surface has a large number of active nucleation sites.

One example group of metal carbonyls has a chemical formula of Mₓ(CO)_{y}, where M is a metal atom, x≥1, and y≥1. Another example group of metal carbonyls has a chemical formula of M(CO)ₓL_{y}, where M is a metal, x≥1, y≥1, and L is a ligand. Non-limiting examples of ligands L include alkenes, dienes, arenes, ethers, amines, nitrosyl, cyanide, carbenes, and cyclopentadienides.

Non-limiting examples of volatile metal carbonyls include: triruthenium dodecacarbonyl (Ru₃(CO)₁₂), iron pentacarbonyl (Fe(CO)₅), nickel tetracarbonyl (Ni(CO)₄), dimanganese decacarbonyl (Mn₂(CO)₁₀, chromium hexacarbonyl (Cr(CO)₆), tungsten hexacarbonyl (W(CO)₆), molybdenum hexacarbonyl (Mo(CO)₆), cobalt tetracarbonyl (Co(CO)₄), ruthenium pentacarbonyl (Ru(CO)₅), hexarhodium hexadecacarbonyl (Rh₆(CO)₁₆), platinum hexacarbonyl (Pt(CO)₆), cobalt tricarbonyl nitrosyl (Co(CO)₃(NO), Ru(CO)₃ (1-Methyl-1,4-cyclohexadiene), Ru(CO)₃ (1-Ethyl-1,4-cyclohexadiene), and Ru(CO)₃ (1-Propyl-1,4-cyclohexadiene).

Non-limiting examples of metal films that may deposited from metal carbonyls include copper (Cu), ruthenium (Ru), iron (Fe), nickel (Ni), manganese (Mn), chromium (Cr), tungsten (W), molybdenum (Mo), cobalt (Co), rhodium (Rh), and platinum (Pt). The metal surfaces can include copper (Cu), molybdenum (Mo), tungsten (W), manganese (Mn), and niobium (Nb).

In one embodiment, a method for ASD includes providing a substrate containing a growth surface that is exposed and a non-growth surface that is exposed, and flowing a deposition gas containing a metal carbonyl precursor to the substrate, the metal carbonyl precursor decomposing on the growth surface such that a metal film is deposited on the growth surface and carbon monoxide (CO) gas is released. The method further includes stopping the flow of the deposition gas to the substrate, and flowing an inhibitor gas to the substrate after stopping the flow of the deposition gas to the substrate. The method further includes repeatedly cycling between flowing the deposition gas to the substrate and flowing the inhibitor gas to the substrate, where the cycling selectively forms the metal film on the growth surface relative to the non-growth surface. The flowing the inhibitor gas increases the selectivity of the metal film formed on the growth surface when compared to the selectivity of the metal film formed on the growth surface without flowing the inhibitor gas. According to an embodiment, the inhibitor gas can include CO gas, CO₂ gas, Cl₂ gas, or NH₃ gas.

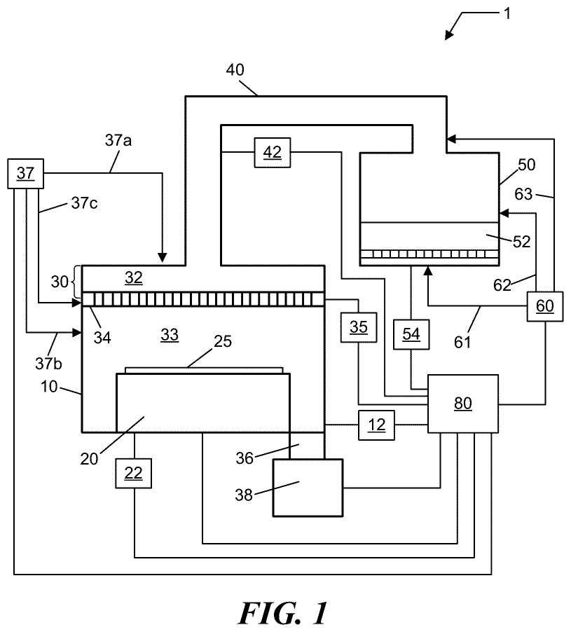

FIG. 1 depicts a schematic view of a deposition system for metal deposition according to an embodiment. The exemplary deposition system 1 may be used for ASD of Ru metal using triruthenium dodecacarbonyl (Ru₃(CO)₁₂) and an inhibitor gas. However, other metal carbonyl precursors may be used for metal deposition without departing from the scope of the invention.

FIG. 1 illustrates a deposition system 1 for depositing a Ru metal film on a substrate from a Ru carbonyl precursor according to an embodiment of the invention. The deposition system 1 includes a process chamber 10 having a substrate holder 20 configured to support a substrate 25 upon which the Ru metal film is formed. The process chamber 10 is coupled to a metal precursor vaporization system 50 via a vapor precursor delivery system 40.

The process chamber 10 is further coupled to a vacuum pumping system 38 through a duct 36, wherein the vacuum pumping system 38 is configured to evacuate the process chamber 10, vapor precursor delivery system 40, and metal precursor vaporization system 50 to a pressure suitable for forming the Ru metal film on the substrate 25, and suitable for vaporization of the Ru carbonyl precursor 52 in the metal precursor vaporization system 50.

The metal precursor vaporization system 50 is configured to store a Ru carbonyl precursor 52, to heat the Ru carbonyl precursor 52 to a temperature sufficient for vaporizing the Ru carbonyl precursor 52, and to introduce Ru carbonyl precursor vapor to the vapor precursor delivery system 40. Ru₃(CO)₁₂ is a solid under the selected heating conditions in the metal precursor vaporization system 50, however, those skilled in the art will appreciate that other ruthenium carbonyl precursors that are liquids under the selected heating conditions can be used without departing from the scope of the invention. Although not shown, the vapor precursor delivery system 40 can include one or more control valves, one or more filters, and a mass flow controller.

In order to achieve the desired temperature for subliming the solid Ru carbonyl precursor 52, the metal precursor vaporization system 50 is coupled to a vaporization temperature control system 54 configured to control the vaporization temperature. For instance, the temperature of the Ru carbonyl precursor 52 may be elevated to between approximately 70° C. to approximately 100° C., or higher, in order to sublime the Ru₃(CO)₁₂. In one example, temperature of the Ru carbonyl precursor 52 may be elevated to between approximately 78° C. to approximately 82° C. in order to sublime the Ru₃(CO)₁₂. As the Ru carbonyl precursor 52 is heated to cause sublimation, a CO gas carrier gas can be passed over or through the Ru carbonyl precursor 52, or any combination thereof. The CO carrier gas contains CO and optionally an inert carrier gas, such as N₂, or a noble gas (i.e., He, Ne, Ar, Kr, or Xe), or a combination thereof.

For example, a gas supply system 60 is coupled to the metal precursor vaporization system 50, and it is configured to, for instance, supply CO gas, an inert gas, or a mixture thereof, beneath the Ru carbonyl precursor 52 via feed line 61, or over the Ru carbonyl precursor 52 via feed line 62. In addition, or in the alternative, the gas supply system 60 is coupled to the vapor precursor delivery system 40 downstream from the metal precursor vaporization system 50 to supply the gas to the vapor of the Ru carbonyl precursor 52 via feed line 63 as or after it enters the vapor precursor delivery system 40. Although not shown, the gas supply system 60 can comprise a CO gas source, an inert gas source, one or more control valves, one or more filters, and a mass flow controller. For instance, the flow rate of the CO carrier gas can be between about 0.1 standard cubic centimeters per minute (sccm) and about 1000 sccm. Alternately, the flow rate of the CO carrier gas can be between about 10 sccm and about 500 sccm. Still alternately, the flow rate of the CO carrier gas can be between about 50 sccm and about 300 sccm. According to embodiments, the flow rate of the CO gas can range from approximately 0.1 sccm to approximately 1000 sccm. Alternately, the flow rate of the CO gas can be between about 1 sccm and about 500 sccm.

Downstream from the metal precursor vaporization system 50, the process gas containing the Ru carbonyl precursor vapor and the CO carrier gas flows through the vapor precursor delivery system 40 until it enters the process chamber 10 via a vapor distribution system 30 coupled thereto. The vapor precursor delivery system 40 can be coupled to a vapor line temperature control system 42 in order to control the vapor line temperature and prevent decomposition of the Ru carbonyl precursor vapor as well as condensation of the Ru carbonyl precursor vapor. Although not shown, the vapor precursor delivery system 40 can include one or more control valves, one or more filters, and a mass flow controller.

The vapor distribution system 30, which forms part of and is coupled to the process chamber 10, comprises a vapor distribution plenum 32 within which the vapor disperses prior to passing through a vapor distribution plate 34 and entering a processing zone 33 above substrate 25. In addition, the vapor distribution plate 34 can be coupled to a distribution plate temperature control system 35 configured to control the temperature of the vapor distribution plate 34.

Once the process gas containing the Ru carbonyl precursor vapor enters the processing zone 33 of process chamber 10, the Ru carbonyl precursor vapor thermally decomposes upon adsorption at the substrate surface due to the elevated temperature of the substrate 25, and a Ru metal layer is formed on the substrate 25. The substrate holder 20 is configured to elevate the temperature of the substrate 25 by virtue of the substrate holder 20 being coupled to a substrate temperature control system 22. For example, the substrate temperature control system 22 can be configured to elevate the temperature of the substrate 25 up to approximately 500° C. In one example, the temperature of the substrate 25 can be maintained between about 150° C. and about 250° C. during Ru metal deposition. In another example, the temperature of the substrate 25 can be maintained between about 190° C. and about 200° C. during Ru metal deposition. Additionally, the process chamber 10 can be coupled to a chamber temperature control system 12 configured to control the temperature of the chamber walls.

The CO gas in the CO carrier gas is used to reduce premature decomposition of the Ru carbonyl precursor vapor prior to entering the process chamber 10, including in the metal precursor vaporization system 50, the vapor precursor delivery system 40, and the vapor distribution system 30. The addition of the CO gas to the Ru carbonyl precursor vapor allows for increasing the vaporization temperature from approximately 40° C. to approximately 100° C., or higher. The elevated temperature increases the vapor pressure of the ruthenium carbonyl precursor, resulting in increased delivery of the Ru carbonyl precursor to the process chamber 10 and, hence, increased deposition rate of the Ru metal on the substrate 25.

The deposition system 1 contains an additional gas source 37 coupled to the process chamber 10. The additional gas source 37 is configured to add an additional gas to the process gas containing the metal-carbonyl precursor vapor and the CO gas. According to an embodiment of the invention, the additional gas can contain an inert gas (e.g., N₂, a noble gas (i.e., He, Ne, Ar, Kr, or Xe), or a combination thereof), a CO gas, or a combination thereof. According to an embodiment, the additional gas can contain an inhibitor gas comprising CO gas, CO₂ gas, Cl₂ gas, or NH₃ gas. The additional gas source 37 can be coupled to the vapor distribution system 30 via feed line 37a and configured to add the additional gas to the process gas in the vapor distribution plenum 32 before the process gas passes through the vapor distribution plate 34 into the processing zone 33. Alternately, the additional gas source 37 can be coupled to the process chamber 10 via feed line 37b and configured to add the additional gas to the process gas in the processing zone 33 above the substrate 25 in the process chamber 10 after the process gas passes through the vapor distribution plate 34. Still alternately, the additional gas source 37 can be coupled to the vapor distribution system 30 via feed line 37c and configured to add the additional gas to the process gas in the vapor distribution plate 34.

As will be appreciated by those skilled in the art, the additional gas can be added to the process gas at other locations in the vapor distribution system 30 and the process chamber 10 without departing from the scope of the invention. According to embodiments of the invention, a flow rate of the additional gas can range from approximately 10 sccm to approximately 1000 sccm. Alternately, the flow rate of the additional gas can be between about 100 sccm and about 300 sccm.

Still referring to FIG. 1, the deposition system 1 can further include a control system 80 configured to operate and control the operation of the deposition system 1. The control system 80 is coupled to the process chamber 10, the substrate holder 20, the substrate temperature control system 22, the chamber temperature control system 12, the vapor distribution system 30, the vapor precursor delivery system 40, the metal precursor vaporization system 50, the vaporization temperature control system 54, and the gas supply system 60.

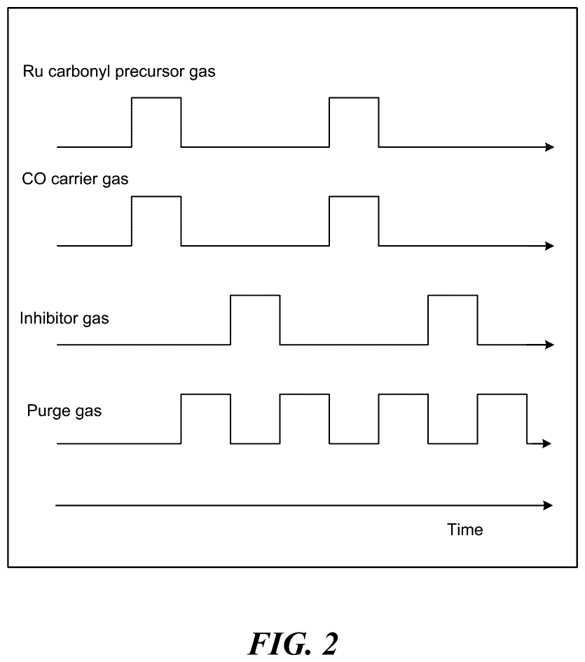

FIG. 2 schematically shows gas flows during cyclical Ru metal deposition according to an embodiment. The cyclical deposition process includes a plurality of deposition cycles that include alternating exposures of a 1) deposition gas containing a Ru carbonyl precursor and CO carrier gas, and 2) an inhibitor gas. The cyclical deposition process can also include flowing a purge gas in between the alternating exposures of the deposition gas and the inhibitor gas. In another embodiment, the purge gas may be flowed during the entire cyclical deposition process. The purge gas is effective in removing the Ru carbonyl precursor gas, the inhibitor gas, and any reaction products from the process chamber. Only two deposition cycles are shown in FIG. 2, but any number of deposition cycles may be carried out until the Ru metal film has a desired thickness.

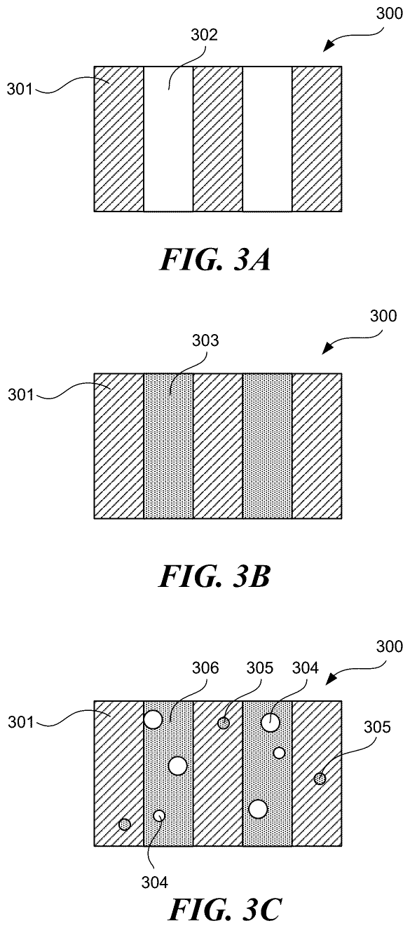

FIGS. 3A and 3B schematically shows selective metal deposition on a growth surface relative to a non-growth surface according to an embodiment. FIG. 3A shows a top-down view of a substrate 300 containing a growth surface 302 and a non-growth surface 301. In one example, the growth surface 302 includes an exposed metal surface of a metal layer and the non-growth surface 301 includes an exposed surface of a dielectric material. FIG. 3B shows a top-down view of the substrate 300 following a cyclical metal deposition where a metal layer 303 is selectively deposited on the growth surface 302 relative to the non-growth surface 301. The metal layer 303 is continuous and with no gaps exposing the underlying growth surface 302. Further, there is no metal deposited on the non-growth surface 301. For comparison, FIG. 3C shows a top-down view of the substrate 300 following a non-cyclical metal deposition where a metal layer 306 is deposited on the growth surface 302 but the metal layer 306 is not continuous and has voids 304 that expose the underlying growth surface 302. Further, the metal deposition is not selective since metal nuclei 305 are deposited at defects on the non-growth surface 301.

The continuous metal layer 303 in FIG. 3B may serve as cap layer on the growth surface 302. In one example, the cap layer may include Ru metal that is selectively deposited on a surface of a Cu metal feature. Cu metallization with a continuous and void-free Ru metal cap layer is preferred for improved electrical properties of the microelectronic devices. For example, a uniform and continuous Ru metal film used as cap layer can reduce electromigration of Cu metal.

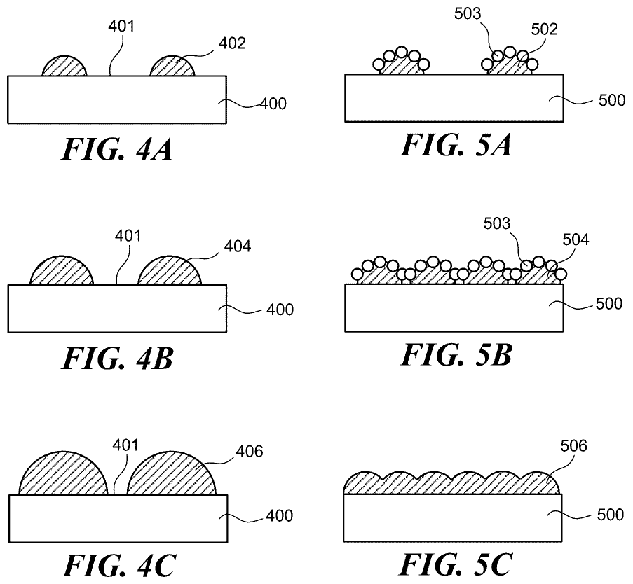

FIGS. 4A-4C schematically show through cross-sectional views a non-cyclical deposition where metal is deposited on a growth surface. As shown in FIG. 4A, initially, small metal nuclei 402 are formed on a growth surface 401 of the substrate 400, and further metal deposition shown in FIGS. 4B and 4C preferentially forms larger metal nuclei 404 and 406, respectively, with open areas on the growth surface 401.

The inventors have realized that flowing the inhibitor gas when the metal deposition is interrupted, improves the saturation of the adsorbed inhibitor species on the metal nuclei, and this results in more uniform and continuous metal film. FIGS. 5A-5C schematically show through cross-sectional views a cyclical deposition where metal is deposited on a growth surface. The cyclical deposition uses inhibitor gas flow for saturating metal nuclei on the substrate with adsorbed inhibitor species when the deposition gas containing the metal carbonyl precursor gas is not flowing. The adsorbed inhibitor species hinder further metal deposition on the metal nuclei. Without the adsorbed inhibitor species on the metal nuclei, further metal deposition proceeds faster on metal nuclei than on the substrate between the metal nuclei.

In FIG. 5A, initial metal deposition forms metal nuclei 502 on the growth surface 501 of the substrate 500, where the metal nuclei 502 contain adsorbed inhibitor species 503 that hinder further metal deposition on the metal nuclei 502. Further metal deposition, results in metal deposition on other nucleation sites on the growth surface 501 and formation of numerous small metal nuclei 504 as shown in FIG. 5B. Still further metal deposition results in a uniform thin and continuous metal film 506 as shown FIG. 5C, where the metal film 506 is thinner and smoother than the metal film 504 in FIG. 5B.

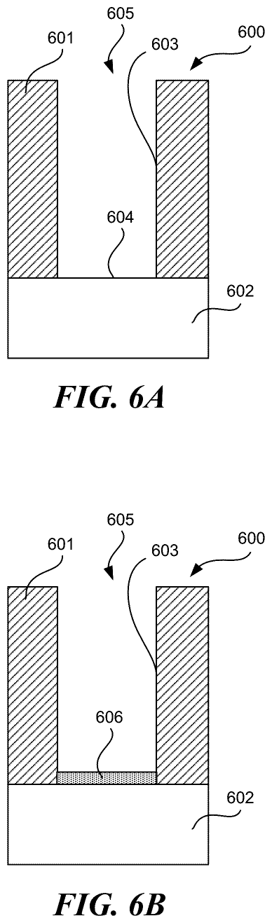

Embodiments of the invention may be applied to substrates with defining features to receive a deposition of material such as a metal. The features can, for example, include a trench or a via, or both. FIGS. 6A and 6B schematically show selective metal deposition on a growth surface relative to a non-growth surface in a recessed feature according to an embodiment.

FIG. 6A shows a cross-sectional view of a substrate 600 containing a recessed feature 605 in a first material 601. The recessed feature 605 contains sidewalls of the first material 601 with a non-growth surface 603, and a second material 602 with a growth surface 604 at the bottom of the recessed feature 605. In one example, the growth surface 604 includes an exposed metal surface of a metal layer and the non-growth surface 603 includes an exposed surface of dielectric material. A diameter of the recessed feature 605 can be less than 30 nm, less than 20 nm, less than 10 nm, or less than 5 nm. A diameter of the recessed feature 605 can be between 20 nm and 30 nm, between 10 nm and 20 nm, between 5 nm and 10 nm, or between 3 nm and 5 nm, for example. A depth of the recessed feature 605 can, for example be greater 20 nm, greater than 50 nm, greater than 100 nm, or greater than 200 nm. The recessed feature 605 can, for example, have an aspect ratio (AR, depth:width) between 2:1 and 20:1, between 2:1 and 10:1, or between 2:1 and 5:1.

FIG. 6B shows the substrate 600 following cyclical metal deposition where a metal layer 606 is selectively deposited on the growth surface 604 relative to the non-growth surface 603. The metal layer 606 is continuous with no gaps exposing the underlying growth surface 604. Further, no or little metal is deposited on the non-growth surface 603. The continuous metal layer 606 in FIG. 6B may serve as cap layer on growth surface 604. In one example, the cap layer may include Ru metal that is selectively deposited on a surface of a Cu metal feature.

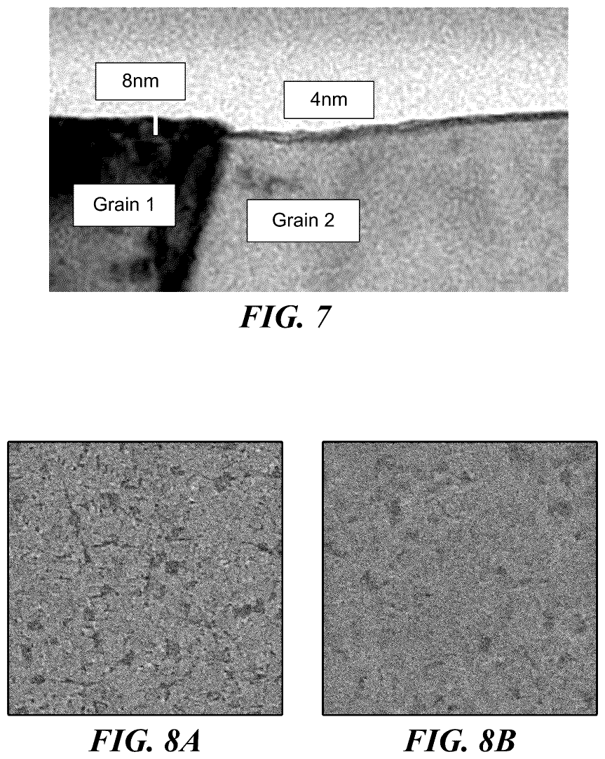

FIG. 7 shows a cross-sectional micrograph image of Ru metal deposition on Cu metal grains with different grain orientations. The Ru metal film was deposited using continuous flow of Ru₃(CO)₁₂ and carbon monoxide (CO) carrier gas. The thickness of the Ru metal film on Cu metal grain 1 was 8 nm and the thickness of the Ru metal film on Cu metal grain 2 was 4 nm. This illustrates that the crystallographic structure of the different Cu metal grains can affect the thickness of the deposited Ru metal film.

FIGS. 8A and 8B show top view scanning electron micrographs (SEM) of Ru metal films deposited on Cu metal films. The substrate contained 100 nm of Cu metal deposited by physical vapor deposition (PVD). FIG. 8A shows a top view of a Ru metal film deposited on the Cu metal, where an average thickness of the Ru metal film was about 2 nm. The Ru metal film was deposited using a continuous flow of Ru₃(CO)₁₂ and carbon monoxide (CO) carrier gas. The darker areas in FIG. 8A are believed to be gaps (pinholes) in the Ru metal film that expose the Cu metal surface through the Ru metal film. The formation of the gaps is attributed to different Cu metal grain with different crystallographic orientations that affect the deposition rate of the Ru metal film.

FIG. 8B shows a top view of a Ru metal film deposited on the Cu metal using cyclical metal deposition of 1) flowing the of Ru₃(CO)₁₂ and carbon monoxide (CO) carrier gas to the substrate, and 2) flowing the CO inhibitor gas to the substrate. The average thickness of the Ru metal film was about 2 nm. A comparison between FIGS. 8A and 8B shows fewer gaps (pinholes) in the Ru metal film FIG. 8B. This is attributed to an increase the thickness uniformity of the Ru metal film over the plurality of different Cu grain orientations in FIG. 8B when compared to the thickness uniformity of the Ru metal film over the different Cu grain orientations without presence of the inhibitor gas in FIG. 8A. In other words, the cyclic Ru metal deposition process reduces the thickness variation across different Cu grain orientations.

Area selective deposition (ASD) of smooth and continuous metal films for microelectronic devices have been described in several embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method for area selective deposition, the method comprising:
providing a substrate containing a growth surface that is exposed and an non-growth surface that is exposed;
flowing a deposition gas containing a metal carbonyl precursor to the substrate, the metal carbonyl precursor decomposing on the growth surface such that a metal film is deposited on the growth surface and carbon monoxide (CO) gas is released;
stopping the flow of the deposition gas to the substrate;
flowing an inhibitor gas to the substrate after stopping the flow of the deposition gas to the substrate; and
repeatedly cycling between flowing the deposition gas to the substrate and flowing the inhibitor gas to the substrate, wherein the cycling selectively forms the metal film on the growth surface relative to the non-growth surface, and wherein the flowing the inhibitor gas increases the selectivity of the metal film formed on the growth surface when compared to the selectivity of the metal film formed on the growth surface without flowing the inhibitor gas.

2. The method of claim 1, wherein the metal film contains copper (Cu), ruthenium (Ru), iron (Fe), nickel (Ni), manganese (Mn), chromium (Cr), tungsten (W), molybdenum (Mo), cobalt (Co), rhodium (Rh), or platinum (Pt).

3. The method of claim 1, wherein the metal surface contains copper (Cu), ruthenium (Ru), molybdenum (Mo), tungsten (W), manganese (Mn), or niobium (Nb).

4. The method of claim 1, wherein the inhibitor gas contains CO gas, CO₂ gas, Cl₂ gas, or NH₃ gas.

5. The method of claim 1, wherein the metal carbonyl precursor contains Ru₃(CO)₁₂ and the metal film contains Ru metal.

6. The method of claim 1, wherein the growth surface and the non-growth surface are in the same horizontal plane.

7. The method of claim 1, wherein the growth surface is located at a bottom of a recessed feature formed in a material containing the non-growth surface.

8. The method of claim 1, wherein the growth surface includes a metal surface and the non-growth surface includes a dielectric material.

9. The method of claim 1, wherein the flowing the inhibitor gas increases the density of metal nuclei on the growth surface when compared to the density of the metal nuclei on the growth surface without presence of the inhibitor gas.

10. The method of claim 1, wherein the deposition gas further contains a CO carrier gas.

11. A method for area selective deposition, the method comprising:
providing a substrate containing a metal surface that is exposed and a non-metal surface that is exposed;
flowing a deposition gas containing a ruthenium (Ru) carbonyl precursor to the substrate, the ruthenium carbonyl precursor decomposing on the metal surface such that a Ru metal film is deposited on the metal surface and carbon monoxide (CO) gas is released;
stopping the flow of the deposition gas to the substrate;
flowing an inhibitor gas to the substrate after stopping the flow of the deposition gas to the substrate; and
repeatedly cycling between flowing the deposition gas to the substrate and flowing the inhibitor gas to the substrate, wherein the cycling selectively forms the Ru metal film on the metal surface relative to the dielectric surface, and wherein the flowing the inhibitor gas increases the selectivity of the Ru metal film formed on the metal surface when compared to the selectivity of the Ru metal film formed on the metal surface without flowing the inhibitor gas.

12. The method of claim 11, wherein the metal film contains copper (Cu), ruthenium (Ru), iron (Fe), nickel (Ni), manganese (Mn), chromium (Cr), tungsten (W), molybdenum (Mo), cobalt (Co), rhodium (Rh), or platinum (Pt).

13. The method of claim 11, wherein the metal surface includes copper (Cu), ruthenium (Ru), molybdenum (Mo), tungsten (W), manganese (Mn), or niobium (Nb).

14. The method of claim 11, wherein the inhibitor gas contains CO gas, CO₂ gas, Cl₂ gas, or NH₃ gas.

15. The method of claim 11, wherein the growth surface includes a metal surface and the non-growth surface includes a dielectric material.

16. The method of claim 11, wherein the flowing the inhibitor gas increases the density of metal nuclei on the growth surface when compared to the density of the metal nuclei on the growth surface without presence of the inhibitor gas.

17. The method of claim 11, wherein the deposition gas further contains a CO carrier gas.

18. A method for area selective deposition, the method comprising:
providing a substrate containing a metal surface that is exposed and a non-metal surface that is exposed, where the metal surface has a plurality of different grain orientations;
flowing a deposition gas containing a metal carbonyl precursor to the substrate, the metal carbonyl precursor decomposing on the metal surface such that a metal film is deposited on the metal surface and carbon monoxide (CO) gas is released;
stopping the flow of the deposition gas to the substrate;
flowing an inhibitor gas to the substrate after stopping the flow of the deposition gas to the substrate; and
repeatedly cycling between flowing the deposition gas to the substrate and flowing the inhibitor gas to the substrate, wherein the cycling selectively forms the metal film on the metal surface relative to the dielectric surface, and wherein the flowing the inhibitor gas increases the thickness uniformity of the metal film formed on the plurality of different grain orientations when compared to the selectivity of the metal film formed on the plurality of different orientations without flowing the inhibitor gas.

19. The method of claim 18, wherein the metal film contains copper (Cu), ruthenium (Ru), iron (Fe), nickel (Ni), manganese (Mn), chromium (Cr), tungsten (W), molybdenum (Mo), cobalt (Co), rhodium (Rh), or platinum (Pt), and wherein the metal surface includes copper (Cu), ruthenium (Ru), molybdenum (Mo), tungsten (W), manganese (Mn), or niobium (Nb).

20. The method of claim 18, wherein the inhibitor gas contains CO gas, CO₂ gas, Cl₂ gas, or NH₃ gas.
